(19) United States
(12) Patent Application Publication
(10) Pub. No.: US 2026/0262431 A1
(43) Pub. Date: Sep. 3, 2026

(54) Electronic Device, Inkjet Printing Apparatus, And Method Of Manufacturing Display Panel Using The Same

(71) Applicant: Samsung Display Co., Ltd., Yongin-si (KR)

(72) Inventor: Futoshi Yoshida, Yokohama-shi (JP)

(73) Assignee: Samsung Display Co., Ltd., Yongin-si (KR)

(21) Appl. No.: 19/539,441

(22) Filed: Feb. 13, 2026

(30) Foreign Application Priority Data
Feb. 28, 2025 (JP) 2025-032079

(51) Int. Cl. H10K 71/00; B41J 2/01

(52) U.S. Cl. CPC H10K 71/00; B41J 2/01

(57) ABSTRACT

An inkjet printing apparatus includes a first stage, a second stage having a substrate thereon, and a head unit movable in a first direction. The head unit includes a housing on the substrate, a plurality of print heads in the housing, nozzles on a lower surface of each print head, and an ink supply unit. A mask is disposed between the head unit and the second stage and has a plurality of openings. The mask includes an inner surface defining the openings with a water-repellent property, a first portion adjacent to each opening with a first thickness, and a second portion extending from the first portion in the first direction with a smaller thickness.

### CROSS-REFERENCE TO RELATED APPLICATIONS

This application claims priority under 35 U.S.C. § 119 to Japanese Patent Application No. JP2025-032079, filed on February 28, 2025, the entire contents of which are hereby incorporated by reference.

### BACKGROUND

The present disclosure herein relates to an electronic device, an inkjet printing apparatus, and a method of manufacturing a display panel using the same.

As organic light-emitting diode displays (OLEDs) generally have superior luminance and viewing angle characteristics, they are attracting attention as next-generation flat panel displays and, unlike liquid crystal displays, do not require a separate light source. Because the organic light-emitting diode displays do not require a separate light source, they may be manufactured in a lightweight and thin form. Furthermore, the organic light-emitting diode displays have characteristics such as low power consumption, high luminance, and high response speed.

The organic light-emitting diode display includes a plurality of light-emitting elements, each including an anode, an organic light-emitting layer, and a cathode. Holes and electrons are injected from the anode and the cathode, respectively, into the organic light-emitting layer to form excitons, and the excitons transition to a ground state, causing the light-emitting element to emit light.

When manufacturing the light-emitting element, the organic light-emitting layer is formed using an inkjet printing apparatus. An organic material (or ink) for forming the organic light-emitting layer is ejected onto a substrate from the inkjet printing apparatus, thereby forming the organic light-emitting layer.

Manufacturing the organic light-emitting diode displays requires a high-resolution, precise patterning process. As the pixel size of the organic light-emitting diode displays with high resolution becomes smaller, the inkjet printing apparatus must eject a smaller amount of ink. In a case in which the amount of ink ejected from the inkjet printing apparatus is not precisely controlled, a defective organic light-emitting layer is formed. Therefore, the development of an inkjet printing apparatus capable of precisely controlling the amount of ink is required.

### SUMMARY

The present disclosure provides an inkjet printing apparatus capable of reducing the defect rate of an organic light-emitting layer.

An aspect of the present disclosure provides an inkjet printing apparatus including a first stage, a second stage disposed on the first stage and having a substrate disposed thereon, a head unit configured to move in a first direction and including a housing, the head unit located above the substrate, a plurality of print heads disposed inside the housing, a plurality of nozzles respectively disposed on a lower surface of each of the print heads, and an ink supply unit for supplying ink to the print heads, and a mask disposed between the head unit and the second stage and having a plurality of openings defined therein, wherein the mask may include an inner surface defining each opening and having a water-repellent property, a first portion adjacent to each opening and having a first thickness, and a second portion extending from a lower portion of the first portion in the first direction and having a second thickness smaller than the first thickness.

In an aspect, the inkjet printing apparatus may further include a mask slide disposed on a lower surface of the housing and on an upper surface of the mask and configured to move in a second direction crossing the first direction.

In an aspect, the inkjet printing apparatus may further include a cleaning unit disposed on the first stage and configured to move in the second direction.

In an aspect, the nozzles may include a plurality of first nozzles defined as a first nozzle group and arranged in the first direction, a plurality of second nozzles defined as a second nozzle group and arranged in the first direction, and a plurality of third nozzles defined as a third nozzle group and arranged in the first direction, wherein the first nozzle group, the second nozzle group, and the third nozzle group may be arranged in a second direction crossing the first direction.

In an aspect, the first nozzles and the third nozzles may be arranged in corresponding identical columns in the second direction, and the second nozzles may be arranged in columns between the columns in which the first nozzles are arranged.

In an aspect, in plan view, the mask may include a first mask portion in which the first nozzles, the second nozzles, and the third nozzles overlap the openings.

In an aspect, in plan view, the mask may include a second mask portion in which the first nozzles, the second nozzles, and the third nozzles do not overlap the openings.

In an aspect, in plan view, the diameter of each of the first nozzles, the second nozzles, and the third nozzles may be smaller than the size of each of the openings.

In an aspect, a first ink pattern may be formed on an upper surface of the second portion.

In an aspect, the inkjet printing apparatus may further include a pixel defining film disposed on the substrate and having a plurality of pixel openings defined therein, wherein an inner side surface of the pixel defining film having each of the pixel openings defined therein may have a hydrophilic property, and an upper surface of the pixel defining film between the pixel openings may have a water-repellent property.

In an aspect, a second ink pattern may be formed within the pixel openings.

In an aspect, the second stage of the inkjet printing apparatus may further include an adsorption hole.

In an aspect, the inkjet printing apparatus may further include a frame connecting the first stage and the head unit to each other.

In an aspect of the present disclosure, a method for manufacturing a display panel may include: preparing a first stage; disposing a second stage on the first stage; disposing, on the second stage, a substrate, a first electrode disposed on the substrate, and a pixel defining film disposed on the first electrode and having a plurality of pixel openings defined therein and exposing a portion of the first electrode; disposing a head unit configured to move in a first direction and including a housing, the head unit and the housing located above the substrate, a plurality of print heads disposed inside the housing, a plurality of nozzles respectively disposed on a lower surface of each of the print heads, and an ink supply unit configured to supply ink to the print heads; disposing a mask, in which a plurality of openings are defined, between the head unit and the second stage; ejecting the ink from the nozzles toward the pixel openings; curing the ink to form a light-emitting layer; and providing a second electrode on the light-emitting layer.

In an aspect, the mask may include an inner surface defining each of the openings and having a water-repellent property, a first portion adjacent to each of the openings and having a first thickness, and a second portion extending from a lower portion of the first portion in the first direction and having a second thickness smaller than the first thickness.

In an aspect, the method for manufacturing the display panel may further include disposing a mask slider, which moves in a second direction crossing the first direction, on a lower surface of the housing and on an upper surface of the mask.

In an aspect, the method for manufacturing the display panel may further include disposing a cleaning unit, which moves in a second direction crossing the first direction, on the first stage.

In an aspect, the method for manufacturing the display panel may further include disposing an inspection unit on the second stage and inspecting a discharge amount of the ink by the inspection unit.

In an aspect of the present disclosure, an electronic device includes a display device for displaying an image and a processor for processing an image signal and providing the image signal to the display device, wherein the display device may include pixels manufactured by: preparing a first stage; disposing a second stage on the first stage; disposing, on the second stage, a substrate, a first electrode disposed on the substrate, and a pixel defining film disposed on the first electrode and having a plurality of pixel openings defined therein and exposing a portion of the first electrode; disposing a head unit configured to move in a first direction and including a housing, the housing and head unit located above the substrate, a plurality of print heads disposed inside the housing, a plurality of nozzles respectively disposed on a lower surface of each of the print heads, and an ink supply unit configured to supply ink to the print heads; disposing a mask, in which a plurality of openings are defined, between the head unit and the second stage; ejecting the ink from the nozzles toward the pixel openings; curing the ink to form a light-emitting layer; and providing a second electrode on the light-emitting layer.

### BRIEF DESCRIPTION OF THE FIGURES

The accompanying drawings are included to provide a further understanding of the present disclosure, and are incorporated in and constitute a part of this specification. The drawings illustrate aspects of the present disclosure and, together with the description, serve to explain principles of the present disclosure. In the drawings:

FIG. 1 is a block diagram of an electronic device according to an aspect of the present disclosure;

FIG. 2 illustrates schematic diagrams of electronic devices according to aspects of the present disclosure;

FIG. 3 illustrates a method of forming an organic light-emitting layer using an inkjet printing apparatus;

FIG. 4 exemplarily illustrates a cross-sectional view of one pixel illustrated in FIG. 3;

FIG. 5 is a perspective view of the inkjet printing apparatus according to an aspect of the present disclosure;

FIG. 6 is a schematic perspective view illustrating a head unit according to an aspect of the present disclosure;

FIG. 7 is a plan view of the inkjet printing apparatus according to an aspect of the present disclosure;

FIG. 8 is a cross-sectional view of the head unit and a mask according to an aspect of the present disclosure;

FIG. 9 is a cross-sectional view of the head unit and a mask according to an aspect of the present disclosure; and

FIGS. 10A to 10E are schematic cross-sectional views illustrating a method of manufacturing a display panel according to an aspect of the present disclosure.

### DETAILED DESCRIPTION

In this specification, it will be understood that when an element (or region, layer, portion, etc.) is referred to as being "on", "connected to" or "coupled to" another element, it can be directly on, connected or coupled to the other element, or intervening elements may be present therebetween.

Like reference numerals refer to like elements throughout. In addition, in the drawings, the thicknesses, ratios, and dimensions of elements are exaggerated for effective description of the technical contents. As used herein, the term "and/or" includes any and all combinations that the associated configurations can define.

Although the terms first, second, etc. may be used herein to describe various components, these components should not be limited by these terms. These terms are used only to distinguish one component, part, region, layer, or portion from another component, part, region, layer, or portion. For example, without departing from the scope of the present disclosure, a first component, a first part, a first region, a first layer, or a first portion may be referred to as a second component, a second part, a second region, a second layer, or a second portion, and similarly, a second component, a second part, a second region, a second layer, or a second portion may also be referred to as a first component, a first part, a first region, a first layer, or a first portion. Singular expressions include plural expressions unless the context clearly indicates otherwise.

In addition, terms, such as "below", "lower", "above", "upper" and the like, are used herein for ease of description to describe one element's relation to another element(s) as illustrated in the figures. The above terms are relative concepts and are described based on the directions indicated in the drawings.

It will be understood that the terms "include" and/or "have", when used in this specification, specify the presence of stated features, integers, steps, operations, elements, components and/or groups thereof, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, aspects of the present disclosure will be described with reference to the accompanying drawings.

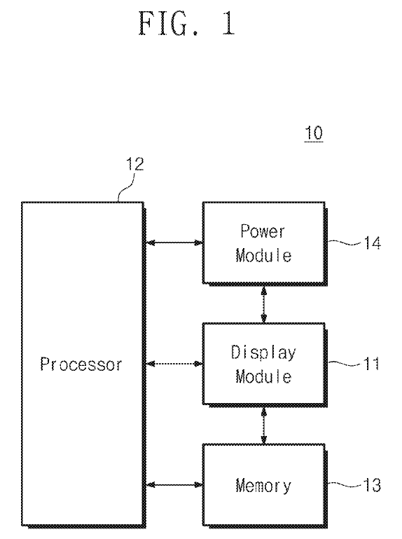

FIG. 1 is a block diagram of an electronic device according to an aspect of the present disclosure.

Referring to FIG. 1, the electronic device 10 according to an aspect of the present disclosure may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), or a controller.

The memory 13 may store data information necessary for the operation of the processor 12 or the display module 11. When the processor 12 executes an application stored in the memory 13, an image data signal and/or an input control signal is transmitted to the display module 11, and the display module 11 may process the received signal and output image information through a display screen.

The power module 14 may include a power supply module, such as a power adapter or a battery device, and a power conversion module that converts power supplied by the power supply module to generate power necessary for the operation of the electronic device 10.

At least one of the components of the electronic device 10 described above may be included in a display device. Furthermore, some of the individual modules functionally included within a single module may be included within the display device, while the others may be provided separately from the display device. For example, the display module 11 may be included in the display device, while the processor 12, the memory 13, and the power module 14 may be provided in the form of other devices within the electronic device 10, rather than within the display device.

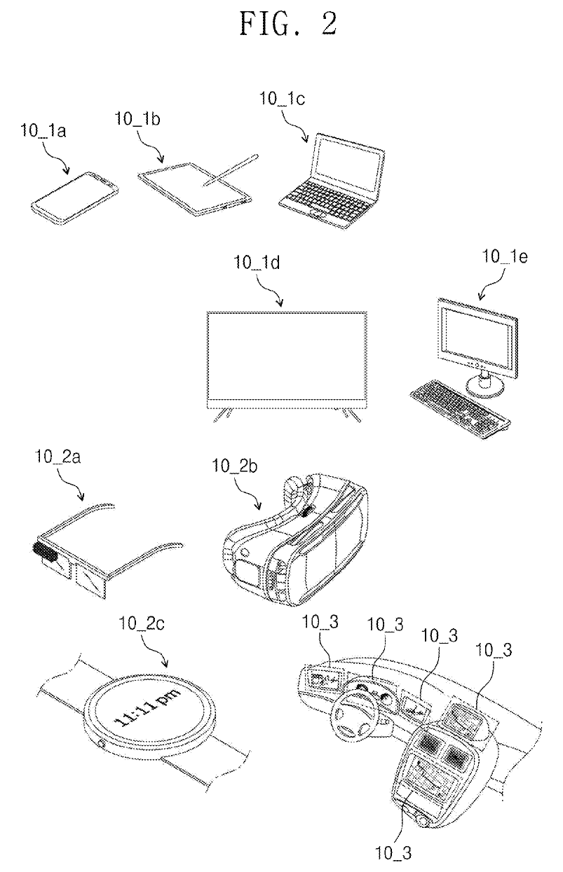

FIG. 2 illustrates schematic diagrams of electronic devices according to aspects of the present disclosure.

Referring to FIG. 2, various electronic devices, to which display devices according to aspects of the present disclosure are applied, may include not only electronic devices for image display, such as a smart phone 10_1a, a tablet PC 10_1b, a laptop 10_1c, a TV 10_1d, and a desktop monitor 10_1e, but also wearable electronic devices including a display module, such as smart glasses 10_2a, a head-mounted display device 10_2b, and a smart watch 10_2c, as well as automotive electronic devices 10_3 including a display module, such as a center information display (CID) disposed on a vehicle’s instrument panel, center fascia, or dashboard, and a room mirror display.

An electronic device may include a display device for displaying an image and a processor for processing an image signal and providing the image signal to the display device. The display device may include pixels manufactured using a method for manufacturing a display panel to be described later.

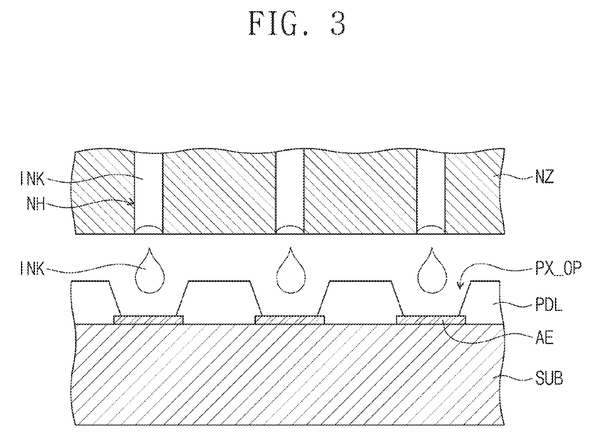

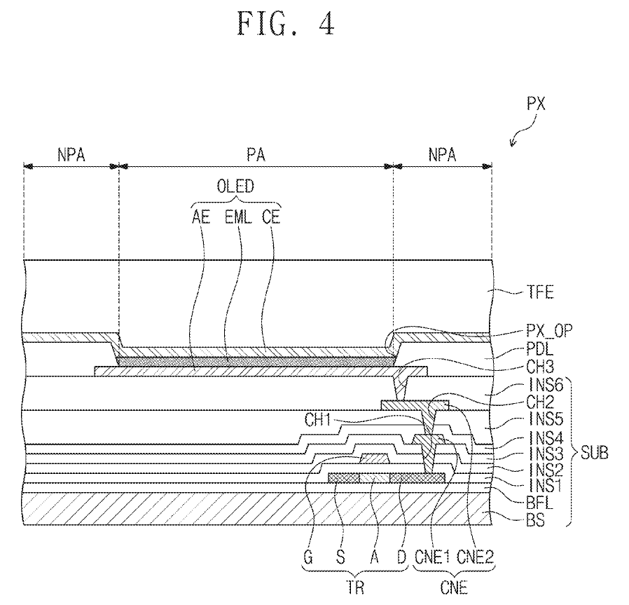

FIG. 3 illustrates a method of forming an organic light-emitting layer using an inkjet printing apparatus. FIG. 4 exemplarily illustrates a cross section of one pixel illustrated in FIG. 3.

For the convenience of explanation, FIG. 3 exemplarily illustrates a cross section of a nozzle NZ portion in which three nozzle holes NH are defined.

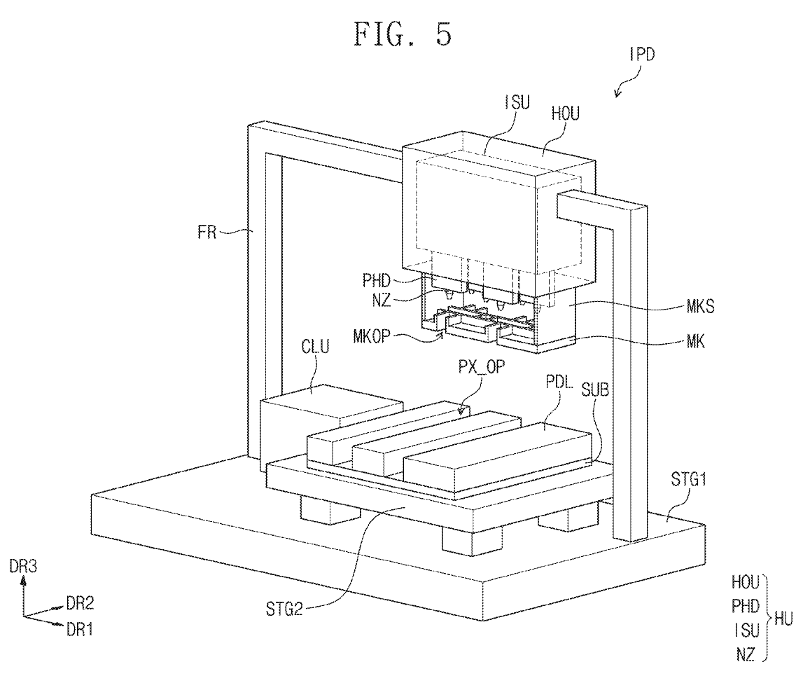

Referring to FIGS. 3 and 4, an inkjet printing apparatus IPD (see FIG. 5) may be used to form a light-emitting layer EML. The pixel PX may include a transistor TR and a light-emitting element OLED connected to the transistor TR. A single pixel PX is illustrated as an example, but a plurality of pixels PX may be disposed on a base layer BS.

The light-emitting element OLED may include a first electrode AE, a second electrode CE, and a light-emitting layer EML. The first electrode AE may be an anode, and the second electrode CE may be a cathode.

The transistor TR and the light-emitting element OLED may be disposed on the base layer BS. The planar region of the base layer BS may be divided into a light-emitting portion PA and a non-light-emitting portion NPA surrounding the light-emitting portion PA. The light-emitting element OLED may be disposed on the light-emitting portion PA.

A buffer layer BFL may be disposed on the base layer BS, and the buffer layer BFL may be an inorganic layer.

Semiconductor patterns S, A, and D may be disposed on the buffer layer BFL. The semiconductor patterns S, A, and D may include polysilicon. Without being limited thereto, however, the semiconductor patterns S, A, and D may also include amorphous silicon or a metal oxide.

The semiconductor patterns S, A, and D may be doped with an N-type dopant or a P-type dopant. The semiconductor patterns S, A, and D may include a highly doped region and a lightly doped region. The highly doped region may have greater conductivity than the lightly doped region and function as a source electrode and a drain electrode of the transistor TR. The lightly doped region may substantially correspond to an active region (or channel) of the transistor.

A source region S, an active region A, and a drain region D of the transistor TR may be formed from the semiconductor patterns S, A, and D. A first insulating layer INS1 may be disposed on the semiconductor patterns S, A, and D. A gate electrode G of the transistor TR may be disposed on the first insulating layer INS1. A second insulating layer INS2 may be disposed on the gate electrode G. A third insulating layer INS3 may be disposed on the second insulating layer INS2.

A connection electrode CNE may be disposed between and connect the transistor TR and the light-emitting element OLED. The connection electrode CNE may include a first connection electrode CNE1 and a second connection electrode CNE2.

The first connection electrode CNE1 may be disposed on the third insulating layer INS3 and connected to the drain region D through a first contact hole CH1 defined in the first to third insulating layers INS1 to INS3. A fourth insulating layer INS4 may be disposed on the first connection electrode CNE1. A fifth insulating layer INS5 may be disposed on the fourth insulating layer INS4.

The second connection electrode CNE2 may be disposed on the fifth insulating layer INS5. The second connection electrode CNE2 may be connected to the first connection electrode CNE1 through a second contact hole CH2 defined in the fifth insulating layer INS5. A sixth insulating layer INS6 may be disposed on the second connection electrode CNE2. The first to sixth insulating layers INS1 to INS6 may be inorganic or organic layers.

The first electrode AE may be disposed on the sixth insulating layer INS6. The first electrode AE may be connected to the second connection electrode CNE2 through a third contact hole CH3 defined in the sixth insulating layer INS6. A pixel defining film PDL exposing a predetermined portion of the first electrode AE may be disposed on the first electrode AE and the sixth insulating layer INS6. A pixel opening PX_OP may be defined in the pixel defining film PDL to expose a predetermined portion of the first electrode AE.

The light-emitting layer EML may be disposed on the first electrode AE. The light-emitting layer EML may be disposed in a region corresponding to the pixel opening PX_OP. The light-emitting layer EML may include an organic material and/or an inorganic material. The light-emitting layer EML may generate light of any one of red, green, and blue colors.

The second electrode CE may be disposed on the light-emitting layer EML. The second electrode CE may be commonly disposed across the pixels PX.

A thin-film encapsulation layer TFE may be disposed on the light-emitting element OLED. The thin-film encapsulation layer TFE may be disposed on the second electrode CE to cover the pixel PX. The thin-film encapsulation layer TFE may include at least two inorganic layers and an organic layer between the inorganic layers. The inorganic layer may protect the pixel PX from moisture/oxygen. The organic layer may protect the pixel PX from foreign substances such as dust particles.

A first voltage may be applied to the first electrode AE through the transistor TR, and a second voltage having a lower level than the first voltage may be applied to the second electrode CE. Holes and electrons injected into the light-emitting layer EML combine to form excitons, and when the excitons transition to a ground state, the light-emitting element OLED may emit light.

FIG. 5 is a perspective view of the inkjet printing apparatus according to an aspect of the present disclosure.

Referring to FIG. 5, the inkjet printing apparatus IPD may include a first stage STG1, a second stage STG2, a head unit HU, a mask MK, a mask slide MKS, a cleaning unit CLU, and a frame FR.

The second stage STG2 may be disposed on the first stage STG1. An adsorption hole (not illustrated) may be defined in the second stage STG2. A substrate SUB may be absorbed by the absorption hole of the second stage STG2 to be secured onto the second stage STG2. The substrate SUB may be disposed on the second stage STG2.

The substrate SUB may move in a second direction DR2 from the second stage STG2. As the substrate SUB moves in the second direction DR2, the head unit HU may appear to move relative to the substrate SUB in the second direction DR2 above the second stage STG2.

The head unit HU may discharge ink INK onto the substrate SUB. The ink INK discharged from the head unit HU may be cured to form the light-emitting layer EML (see FIG. 4). The details of the head unit HU will be described later.

The mask MK may be disposed between the head unit HU and the second stage STG2. The mask MK may have a plurality of openings MKOP defined therein.

The mask slide MKS may be disposed on a lower surface of a housing HOU and an upper surface of the mask MK. The mask slide MKS may move in the second direction DR2. As the mask slide MKS moves, the mask MK may move in the second direction DR2.

The inkjet printing apparatus IPD may further include a cleaning unit CLU disposed on the first stage STG1 and configured to move in the second direction DR2. The cleaning unit CLU may clean the nozzles NZ of print heads PHD while moving in the second direction DR2. The head unit HU is disposed above the cleaning unit CLU, and the nozzles NZ may be cleaned, while the cleaning unit CLU moves in the second direction DR2 and the head unit HU moves in a first direction DR1 crossing, e.g. perpendicular, to the second direction DR2.

The frame FR may connect the first stage STG1 and the head unit HU to each other.

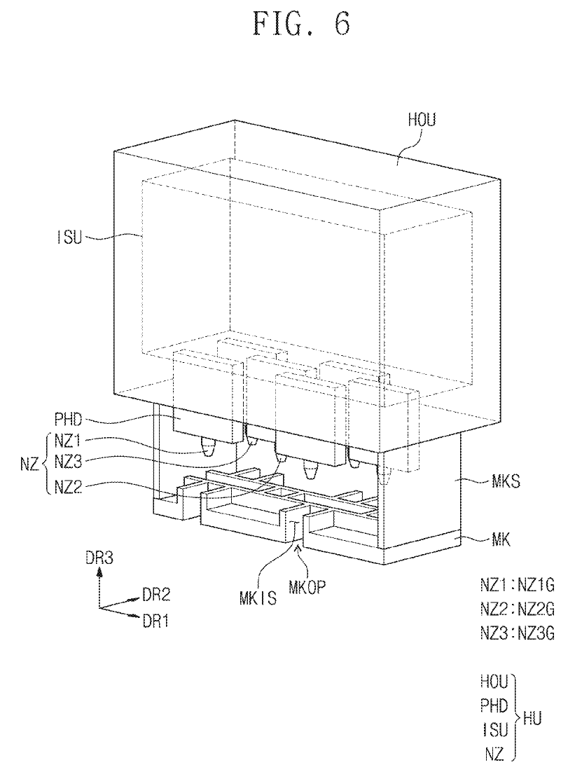

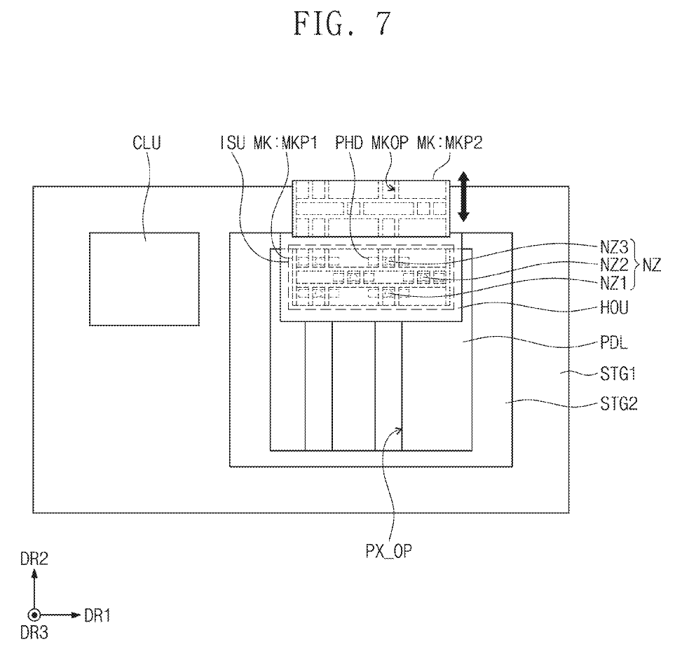

FIG. 6 is a schematic perspective view illustrating a head unit according to an aspect of the present disclosure. FIG. 7 is a plan view of the inkjet printing apparatus according to an aspect of the present disclosure.

For the convenience of explanation, the frame FR and the substrate SUB are omitted in FIG. 7.

Referring to FIGS. 6 and 7, the head unit HU may include a housing HOU located above the substrate SUB (see FIG. 5), a plurality of print heads PHD disposed partially within the housing HOU, a plurality of nozzles NZ1, NZ2, and NZ3, and an ink supply unit ISU.

The nozzles NZ1, NZ2, and NZ3 may be respectively attached to a lower surface of each of the print heads PHD. The nozzles NZ may include a plurality of first nozzles NZ1 arranged in the first direction DR1. The first nozzles NZ1 may be defined as a first nozzle group NZ1G. The nozzles NZ may include a plurality of second nozzles NZ2 arranged in the first direction DR1. The second nozzles NZ2 may be defined as a second nozzle group NZ2G. The nozzles NZ may include a plurality of third nozzles NZ3 arranged in the first direction DR1. The third nozzles NZ3 may be defined as a third nozzle group NZ3G.

The first nozzle group NZ1G, the second nozzle group NZ2G, and the third nozzle group NZ3G may be arranged in the second direction DR2 crossing, e.g.perpendicular to, the first direction DR1. That is, each of the first nozzle group NZ1G, the second nozzle group NZ2G, and the third nozzle group NZ3G may be connected to the ink supply unit ISU so as to be grouped. In FIGS. 6 and 7, the nozzles of the first nozzle group NZ1G, the second nozzle group NZ2G, and the third nozzle group NZ3G are exemplarily illustrated, but the number of the nozzles is not limited thereto as long as the nozzles can form a group.

The first nozzles NZ1 and the third nozzles NZ3 may be arranged in corresponding identical columns in the second direction DR2. The first nozzles NZ1 and the third nozzles NZ3 may overlap each other in the second direction DR2. The second nozzles NZ2 may be arranged in columns between the columns in which the first nozzles NZ1 are arranged. That is, the second nozzles NZ2 may not overlap the first nozzles NZ1 and the third nozzles NZ3 in the second direction DR2. When viewed in the second direction DR2, the second nozzles NZ2 may be disposed between the first nozzles NZ1 and the third nozzles NZ3.

The ink supply unit ISU may be connected to the print heads PHD. The ink supply unit ISU may supply ink INK (see FIG. 2) to the print heads PHD. The ink INK may be discharged from the nozzles NZ1, NZ2, and NZ3 through the ink supply unit ISU.

In plan view, the mask MK may be in a first mask position MKP1 in which the first nozzles NZ1, the second nozzles NZ2, and the third nozzles NZ3 vertically overlap the openings MKOP in the mask. When the nozzles NZ vertically overlap the openings MKOP in the first mask position MKP1 in plan view, even though the ink INK is erroneously ejected from the nozzles NZ, e.g. ejected at an incorrect angle, the erroneously ejected ink INK may be deposited on the mask MK and not on the substrate SUB.

In plan view, the mask MK may include a second mask position MKP2 in which the first nozzles NZ1, the second nozzles NZ2, and the third nozzles NZ3 do not overlap the openings MKOP. The second mask position MKP2 may be obtained when the mask slide MKS moves in the second direction DR2 bringing the mask MK to the second mask position MKP2. In the second mask position MKP2, after the head unit HU moves in the first direction DR1 to the cleaning unit CLU, cleaning of the nozzles NZ may be performed by the cleaning unit CLU.

In plan view, the diameter of each of the first nozzles NZ1, the second nozzles NZ2, and the third nozzles NZ3 may be smaller than the size of the openings MKOP. For example, the diameter of each nozzle may be smaller than the width in the first direction of the openings MKOP. For example, the diameter of each nozzle may be smaller than the width in the second direction of the openings MKOP. For example, the diameter of each nozzle may be smaller than the width of the openings MKOP measured in both the first and second directions. Since the size of the nozzles NZ is smaller than that of the openings MKOP, most of the ink INK (see FIG. 2) ejected from the nozzles NZ may pass through the openings MKOP.

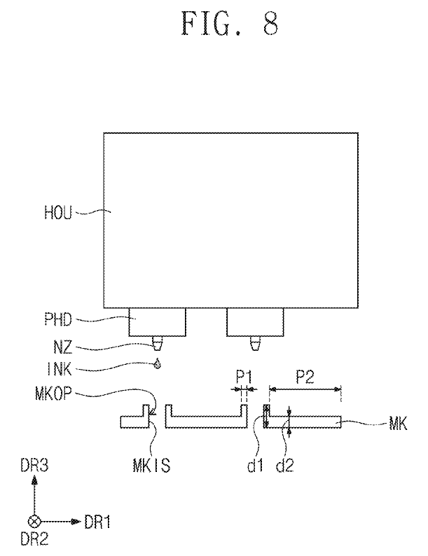

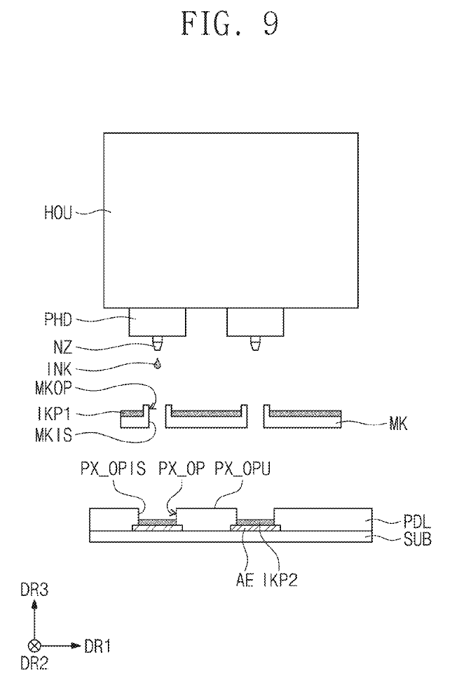

Each of FIGS. 8 and 9 is a cross-sectional view of the head unit and the mask according to an aspect of the present disclosure. For the convenience of explanation, the housing HOU, the print heads PHD, and the nozzles NZ are illustrated in the head unit HU.

Referring to FIGS. 8 and 9, the mask MK may include: a first portion P1 adjacent to each of the openings MKOP and having a first thickness d1; and a second portion P2 extending from a lower portion of the first portion P1 in the first direction DR1 and having a second thickness d2 smaller than the first thickness d1. The first thickness d1 and the second thickness d2 are measured in the vertical direction, e.g. in direction DR3 perpendicular to both direction DR1 and direction DR2.

The mask MK may have a step difference between the first portion P1 and the second portion P2. The mask MK may include an inner surface MKIS defining each of the openings MKOP and having a water-repellent property. When defective ejection of the ink INK occurs and the ink INK is not discharged through the openings MKOP, the ink INK may be discharged onto an upper surface of the second portion P2, forming a first ink pattern IKP1 on the upper surface of the second portion P2. The first ink pattern IKP1 may dry over time on the upper surface of the second portion P2. The first ink pattern IKP1 is allowed to dry on the upper surface of the second portion P2 and no process for removing the first ink pattern IKP1 is needed, thereby improving process convenience.

The inkjet printing apparatus IPD may be located above the substrate SUB (see FIG. 5). The substrate SUB may further include a pixel defining film PDL having a plurality of pixel openings PX_OP defined therein. The inside surface of each pixel openings PX_OP, i.e. an inner side surface PX_OPIS of the pixel defining film PDL, may have a hydrophilic property (see FIG. 9). An upper surface PX_OPU of the pixel defining film PDL may have a water-repellent property.

When the ink INK discharged through the openings MKOP is not deposited into the pixel openings PX_OP but on the upper surface PX_OPU of the pixel defining film PDL, the ink INK may flow back into the pixel openings PX_OP due to the water-repellent property of the upper surface PX_OPU of the pixel defining film PDL and the hydrophilic property of the inner side surface PX_OPIS of the pixel defining film PDL. A second ink pattern IKP2 may be formed inside the pixel openings PX_OP.

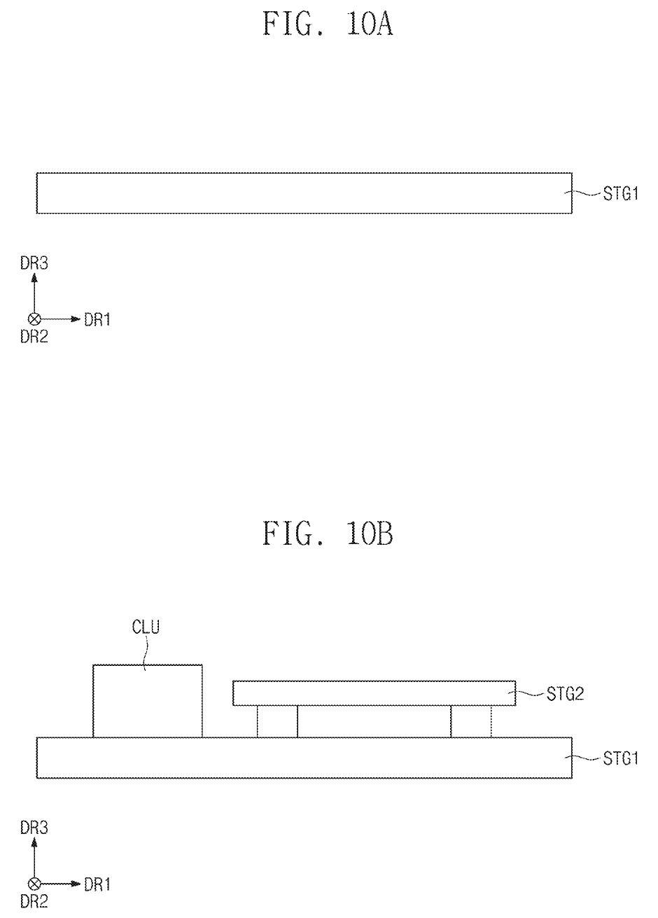

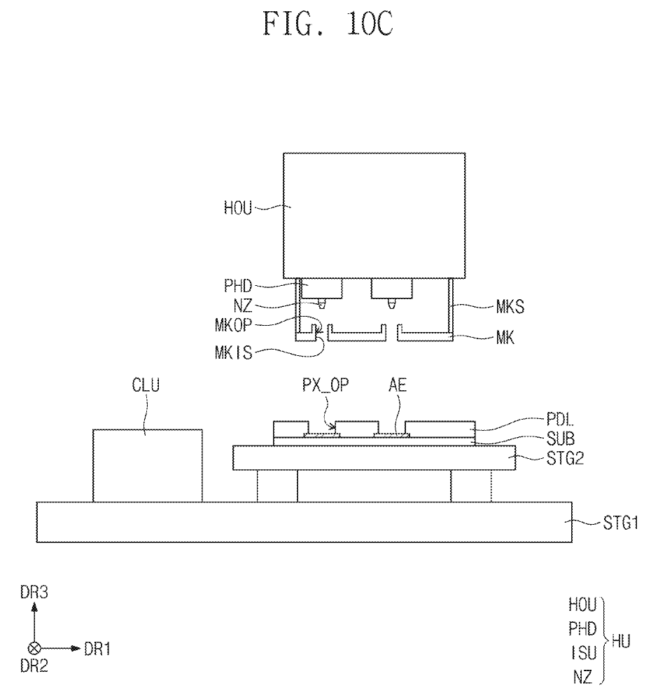

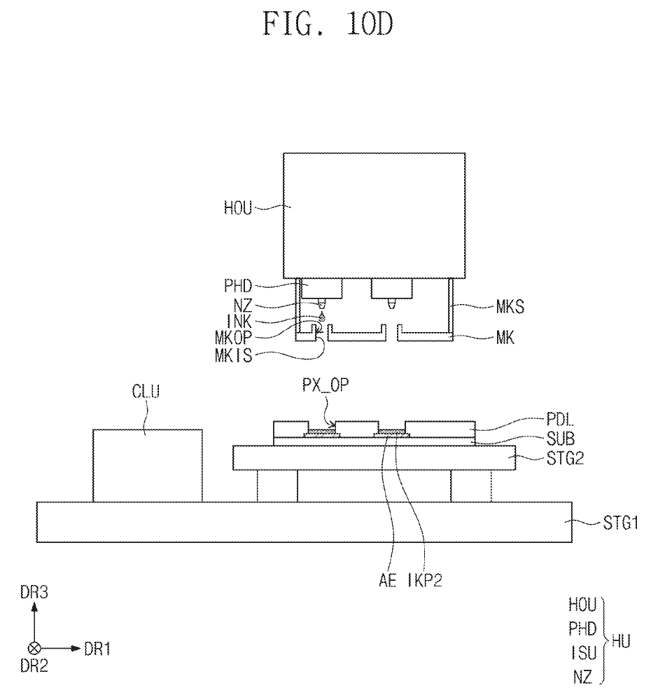

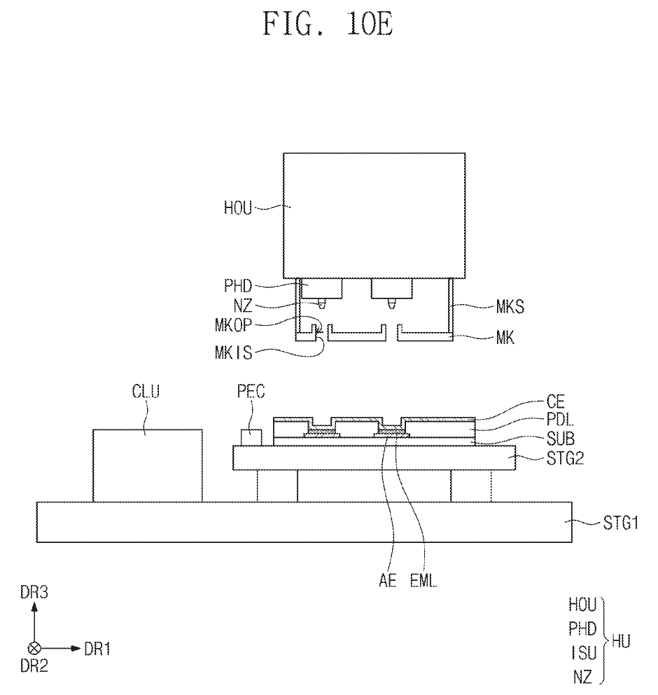

FIGS. 10A to 10E are schematic cross-sectional views illustrating a method of manufacturing a display panel according to an aspect of the present disclosure.

For the convenience of explanation, in FIGS. 10C to 10E, components other than the housing HOU, the print heads PHD, and the nozzles NZ of the head unit HU are omitted.

Referring to FIG. 10A, the method of manufacturing the display panel may include preparing a first stage STG1.

Referring to FIG. 10B, the method of manufacturing the display panel may include disposing a second stage STG2 on the first stage STG1. The method of manufacturing the display panel may further include disposing a cleaning unit CLU disposed on the first stage STG1 and configured to move in the second direction DR2.

Referring to FIG. 10C, the method of manufacturing the display panel may include disposing, on the second stage STG2, a substrate SUB, a first electrode AE disposed on the substrate SUB, and a pixel defining film PDL disposed on the first electrode AE and having pixel openings PX_OP defined therein and exposing a portion of the first electrode AE.

Referring to FIG. 10D, the method of manufacturing the display panel may include disposing a head unit HD (see FIG. 5) configured to move in the first direction DR1 and including a housing HOU located above the substrate SUB, a plurality of print heads PHD disposed partially inside the housing HOU, a plurality of nozzles NZ respectively attached to the lower surface of each of the print heads PHD, and an ink supply unit ISU (see FIG. 5) configured to supply ink INK to the print heads PHD.

The method of manufacturing the display panel may include disposing a mask MK, in which a plurality of openings MKOP are defined, between the head unit HU and the second stage STG2. The method may include ejecting the ink INK from the nozzles NZ toward the pixel openings PX_OP.

The method of manufacturing the display panel may further include disposing a mask slide MKS, which moves in the second direction DR2, on a lower surface of the housing HOU and on an upper surface of the mask MK.

The mask MK may include a plurality of openings MKOP defined within the mask MK. Each of the openings MKOP may defined by an inner surface MKIS of mask MK, the inner surface MKIS having a water-repellent property. The mask MK may also have a first portion P1 (see FIG. 8), and a second portion P2 (see FIG. 8). The ink INK may be ejected from the nozzles NZ and pass through the openings MKOP.

When defective ejection of the ink INK occurs and the ink INK fails to pass through the openings MKOP, the ink INK may be deposited on the upper surface of the mask MK. Accordingly, the mask MK may physically eliminate or reduce pixel defects that may be caused by defective ejection of the ink INK.

The inner surface MKIS of the mask MK has a water-repellent property, and when the ink INK is deposited on the inner surface MKIS of the mask MK, the ink INK may move along the inner surface MKIS of the mask MK. Alternatively, when the ink INK is deposited on the upper portion of first portion P1 of the mask MK, the ink INK may move to the second portion P2 of the mask MK. In this case, the ink INK is allowed to dry on the second portion P2. Due to natural drying of the ink INK on P2, the ink does not get deposited on the substrate and thus repairing the substrate is easier due to the mask MK. Accordingly, defective ejection of the ink INK may be reduced.

Referring to FIG. 10E, the method of manufacturing the display panel may include curing the ink INK (see FIG. 10D) to form a light-emitting layer EML and providing a second electrode CE on the light-emitting layer EML.

The ink INK may be deposited in the pixel openings PX_OP and cured over time to form the light-emitting layer EML. Subsequently, the second electrode CE may be provided on the light-emitting layer EML.

The method of manufacturing the display panel may further include disposing an inspection unit PEC on the second stage STG2 and inspecting a discharge amount of ink INK by the inspection unit PEC. The inspection unit PEC may inspect the pixel openings PX_OP in which there is no discharge amount of ink INK, because, for example, there was a defective discharge of ink that was blocked by the mask. According to an inspection result of the inspection unit PEC, ink INK may be additionally discharged into the pixel openings PX_OP, in which there is no discharge of ink INK, to form the light-emitting layer EML. This process of detecting and fixing a defective discharge of ink is much easier than detecting a defective discharge when the ink is already applied to the substrate.

As described above, when ink fails to pass through the openings MKOP due to defective ejection of the ink, the ink may be deposited on the upper surface of the mask. Accordingly, the mask may physically eliminate or reduce pixel defects that may be caused by defective ejection of the ink.

The inner surface of the mask openings has a water-repellent property and therefore, when ink is deposited on the first portion of the mask, the ink may move through the inner surface of the mask. Alternatively, when the ink is deposited on the upper part of first portion of the mask, the ink may move to the second portion of the mask. In this case, the ink may dry on the second portion. Natural drying of the ink on P2 instead of on the substrate may reduce the repair process. Accordingly, defective ejection of the ink may be reduced.

Although the above has been described with reference to preferred aspects of the present disclosure, those skilled in the art or those of ordinary skill in the art will understand that various modifications and changes can be made to the present disclosure within the scope that does not depart from the spirit and technical field of the present disclosure.

Accordingly, the technical scope of the present disclosure should not be limited to the content described in the detailed description of the specification.

What is claimed is:

1. An inkjet printing apparatus comprising:
a first stage;
a second stage disposed on the first stage and having a substrate disposed thereon;
a head unit configured to move in a first direction, the head unit located above the substrate, the head unit including a housing, a plurality of print heads disposed at least partially inside the housing, a plurality of nozzles respectively attached to a lower surface of each of the print heads, and an ink supply unit configured to supply ink to the print heads; and
a mask disposed between the head unit and the second stage, the mask having a plurality of openings defined therein, each of the plurality of openings having an inner surface defining a respective opening, each inner surface having a water-repellent property,
wherein the mask comprises:
a first portion adjacent to each of the openings and having a first thickness; and
a second portion extending from a lower portion of the first portion in the first direction and having a second thickness smaller than the first thickness.

2. The inkjet printing apparatus of claim 1, further comprising a mask slide disposed on a lower surface of the housing and on an upper surface of the mask, the mask slide configured to move in a second direction crossing the first direction.

3. The inkjet printing apparatus of claim 2, further comprising a cleaning unit disposed on the first stage and configured to move in the second direction.

4. The inkjet printing apparatus of claim 1, wherein the nozzles comprise:
a plurality of first nozzles defined as a first nozzle group and arranged in the first direction;
a plurality of second nozzles defined as a second nozzle group and arranged in the first direction; and
a plurality of third nozzles defined as a third nozzle group and arranged in the first direction,
wherein the first nozzle group, the second nozzle group, and the third nozzle group are arranged in a second direction crossing the first direction.

5. The inkjet printing apparatus of claim 4, wherein the first nozzles and the third nozzles are arranged in corresponding identical columns in the second direction, and the second nozzles are arranged in columns between the columns in which the first and the third nozzles are arranged.

6. The inkjet printing apparatus of claim 4, wherein the openings of mask, in a first mask position, vertically overlap with the first nozzles, the second nozzles, and the third nozzles.

7. The inkjet printing apparatus of claim 4, wherein the opening of the mask, in a second mask position, do not vertically overlap with the first nozzles, the second nozzles, and the third nozzles.

8. The inkjet printing apparatus of claim 4, wherein a diameter of each of the first nozzles, the second nozzles, and the third nozzles is smaller than a width of each of the openings in the first direction.

9. The inkjet printing apparatus of claim 1, wherein a first ink pattern is formed on an upper surface of the second portion.

10. The inkjet printing apparatus of claim 1, further comprising a pixel defining film disposed on the substrate and having a plurality of pixel openings defined therein,
wherein:
an inner side surface of the pixel defining film each defining one of the pixel openings has a hydrophilic property; and
an upper surface of the pixel defining film between the pixel openings has a water-repellent property.

11. The inkjet printing apparatus of claim 10, wherein a second ink pattern is formed within the pixel openings.

12. The inkjet printing apparatus of claim 1, wherein the second stage further comprises an adsorption hole.

13. The inkjet printing apparatus of claim 1, further comprising a frame connecting the first stage and the head unit to each other.

14. A method for manufacturing a display panel, the method comprising:
preparing a first stage;
disposing a second stage on the first stage;
disposing a substrate on the second stage;
disposing a first electrode disposed on the substrate;
disposing a pixel defining film on the first electrode, the pixel defining film having a plurality of pixel openings defined therein, each pixel opening exposing a portion of the first electrode;
providing a head unit above the substrate, the head unit configured to move in a first direction, the head unit including a housing, a plurality of print heads at least partially disposed inside the housing, a plurality of nozzles respectively attached to a lower surface of each of the print heads, and an ink supply unit configured to supply ink to the print heads;
providing a mask between the head unit and the second stage, the mask having a plurality of openings defined therein;
ejecting ink from the nozzles toward the pixel openings;
curing the ink to form a light-emitting layer; and
providing a second electrode on the light-emitting layer.

15. The method of claim 14, wherein the mask comprises:
an inner surface defining one of the openings of the mask, the inner surface having a water-repellent property;
a first portion adjacent to the one of the openings and having a first thickness in the vertical direction; and
a second portion extending from a lower portion of the first portion in the first direction and having a second thickness in the vertical direction smaller than the first thickness.

16. The method of claim 14, further comprising providing a mask slider, the mask slider disposed on a lower surface of the housing and on an upper surface of the mask, the mask slide configured to move in a second direction crossing the first direction.

17. The method of claim 16, further comprising disposing a cleaning unit on the first stage, the cleaning unit configured to move in the second direction.

18. The method of claim 14, further comprising:
disposing an inspection unit on the second stage; and
inspecting a discharge amount of the ink by the inspection unit.

19. An electronic device comprising:
a display device for displaying an image; and
a processor for processing an image signal and providing the image signal to the display device,
wherein the display device comprises pixels manufactured by:
preparing a first stage;
disposing a second stage on the first stage;
disposing a substrate on the second stage;
disposing a first electrode disposed on the substrate;
disposing a pixel defining film on the first electrode, the pixel defining film having a plurality of pixel openings defined therein, each pixel opening exposing a portion of the first electrode;
providing a head unit above the substrate, the head unit configured to move in a first direction, the head unit including a housing, a plurality of print heads at least partially disposed inside the housing, a plurality of nozzles respectively attached to a lower surface of each of the print heads, and an ink supply unit configured to supply ink to the print heads;
providing a mask between the head unit and the second stage, the mask having a plurality of openings defined therein;
ejecting ink from the nozzles toward the pixel openings;
curing the ink to form a light-emitting layer; and
providing a second electrode on the light-emitting layer.
